(19) United States
(12) Patent Application Publication
(10) Pub. No.: US 2005/0051087 A1
(43) Pub. Date: Mar. 10, 2005

(54) Primer tank with nozzle assembly

(75) Inventors: Kuo-Hsing Teng, Hsinchu County (TW); Chia-Ray Tzou, Taipei City (TW); Richard Peng, Hsinchu County (TW); Jian-Hong Chen, Miaoli County (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.,

(21) Appl. No.: 10/658,709

(22) Filed: Sep. 8, 2003

(51) Int. Cl. C23C 16/00

(52) U.S. Cl. 118/715; 427/248.1; 427/255.4; 427/299

(57) ABSTRACT

A primer tank having a nozzle assembly which uniformly distributes nitrogen or other vapor-generating gas against a primer liquid in the tank to generate a primer vapor for the priming of a semiconductor wafer substrate. The nozzle assembly includes a conduit to which is confluently attached a nozzle head having a nozzle plate. Multiple openings are provided in the nozzle plate to substantially uniformly distribute nitrogen or other inert gas against the surface of the primer liquid over a large area to generate a primer mist from the primer liquid and substantially reduce the formation of primer droplets in the tank.

### FIELD OF THE INVENTION

The present invention relates to priming of a wafer substrate to improve adhesion between the substrate and a photoresist layer in the fabrication of semiconductor integrated circuits. More particularly, the present invention relates to a primer tank having a nozzle assembly which facilitates uniform distribution of nitrogen over the surface of liquid primer in the tank to prevent excessive primer mist production and eliminate the presence of liquid particles in a vapor tube that leads from the tank to a wafer processing oven or chamber.

### BACKGROUND OF THE INVENTION

The fabrication of various solid state devices requires the use of planar substrates, or semiconductor wafers, on which integrated circuits are fabricated. The final number, or yield, of functional integrated circuits on a wafer at the end of the IC fabrication process is of utmost importance to semiconductor manufacturers, and increasing the yield of circuits on the wafer is the main goal of semiconductor fabrication. After packaging, the circuits on the wafers are tested, wherein non-functional dies are marked using an inking process and the functional dies on the wafer are separated and sold. IC fabricators increase the yield of dies on a wafer by exploiting economies of scale. Over 1000 dies may be formed on a single wafer which measures from six to twelve inches in diameter.

Various processing steps are used to fabricate integrated circuits on a semiconductor wafer. These steps include deposition of a conducting layer on the silicon wafer substrate; formation of a photoresist or other mask such as titanium oxide or silicon oxide, in the form of the desired metal interconnection pattern, using standard lithographic or photolithographic techniques; subjecting the wafer substrate to a dry etching process to remove the conducting layer from the areas not covered by the mask, thereby etching the conducting layer in the form of the masked pattern on the substrate; removing or stripping the mask layer from the substrate typically using reactive plasma and chlorine gas, thereby exposing the top surface of the conductive interconnect layer; and cooling and drying the wafer substrate by applying water and nitrogen gas to the wafer substrate.

The numerous processing steps outlined above are used to cumulatively apply multiple electrically conductive and insulative layers on the wafer and pattern the layers to form the circuits. The final yield of functional circuits on the wafer depends on proper application of each layer during the process steps. Proper application of those layers depends, in turn, on coating the material in a uniform spread over the surface of the wafer in an economical and efficient manner.

During the photolithography step of semiconductor production, light energy is applied through a reticle mask onto a photoresist material previously deposited on the wafer to define circuit patterns which will be etched in a subsequent processing step to define the circuits on the wafer. Because these circuit patterns on the photoresist represent a two-dimensional configuration of the circuit to be fabricated on the wafer, minimization of particle generation and uniform application of the photoresist material to the wafer are very important. By minimizing or eliminating particle generation during photoresist application, the resolution of the circuit patterns, as well as circuit pattern density, is increased.

Photoresist materials are coated onto the surface of a wafer by dispensing a photoresist fluid typically on the center of the wafer as the wafer rotates at high speeds within a stationary bowl or coater cup. The coater cup catches excess fluids and particles ejected from the rotating wafer during application of the photoresist. The photoresist fluid dispensed onto the center of the wafer is spread outwardly toward the edges of the wafer by surface tension generated by the centrifugal force of the rotating wafer. This facilitates uniform application of the liquid photoresist on the entire surface of the wafer.

Spin coating of photoresist on wafers is carried out in an automated track system using wafer handling equipment which transport the wafers between the various photolithography operation stations, such as vapor prime resist spin coat, develop, baking and chilling stations. Robotic handling of the wafers minimizes particle generation and wafer damage. Automated wafer tracks enable various processing operations to be carried out simultaneously. Two types of automated track systems widely used in the industry are the TEL (Tokyo Electron Limited) track and the SVG (Silicon Valley Group) track.

Early methods of photoresist application presented a number of problems including poor photoresist coating of the substrate wafer, lifting-off of photoresist patterns from devices, and subsequent pattern loss due to portions of the photoresist being carried off by developer when the developer undercut the resist. Undercutting is a deleterious process wherein an aqueous or organic developer migrates along the surface of a polar substrate and causes a photoresist to lose its adhesion with the substrate.

Many of these drawbacks to developer application were solved by priming the substrate with HMDS (hexamethyldisilazane) prior to application of the photoresist. HMDS is typically applied to the substrate after the substrate is subjected to a dehydration bake step and has been found to promote photoresist coating, reduce undercutting and prevent photoresist film lift-off during development. HMDS reacts with both water molecules hydrogen bonded to the silicon substrate and the photoresist applied to the HMDS primer.

Original methods of priming substrates included the application of liquid HMDS or HMDS diluted in various solvents to the substrate surface. Improvements to these methods have included application of the HMDS to the substrate as a vapor. Typically, the substrate is placed in an oven at a reduced pressure and treated with the HMDS vapor. The vapor-application method was more efficient and resulted in more consistent coverage as compared to the former liquid application methods. Today, vapor-priming of substrates is widely used in the manufacture of high-density integrated circuit devices.

Recent methods of vapor priming include utilizing state-of-the-art, in-line track priming in which a substrate is placed on a track and transported to an area where heat and vacuum are applied. The HMDS vapor is generated in a buffer tank and introduced through piping into the area surrounding the substrate when the proper vacuum is achieved. After completion, the vacuum is broken and the substrate is transported to the next operation. A successful vapor priming step facilitates subsequent application of a continuous, uniform film that does not exhibit pinholes, edge pullback, beading, lifting and/or significant undercutting during development.

A typical conventional primer application system 8 is shown in FIG. 1. The system 8 includes an HMDS buffer tank 10 that holds a supply of liquid HMDS primer 12 for priming of a wafer substrate 26 in an oven 24. A level sensor 14 in the tank 10 detects the level of liquid HMDS 12 in the tank 10. A nitrogen inlet pipe 16 extends into the tank 10 and has a discharge end 16a that is disposed above the surface of the liquid HMDS 12. A vapor outlet tube 20 extends from the tank 10 and communicates with the oven 24 in which the wafer substrate 26 is contained. A drain pipe 28 extends from the tank 10 to drain the residual liquid HMDS 12 from the tank 10.

An HMDS primer layer 23 (FIG. 2) is deposited on the substrate 26 as follows. A partial vacuum and elevated temperatures are induced in the oven 24 as nitrogen gas 18 is distributed from the discharge end 16a of the nitrogen inlet pipe 16, against the surface of the liquid HMDS 12. The force of the nitrogen gas 18 striking the liquid HMDS 12 forms an HMDS vapor 22 which is drawn from the tank 10, into the oven 24 through the vapor outlet tube 20. In the oven 24, the HMDS vapor 22 condenses onto the surface of the substrate 26 to form the HMDS primer layer 23 thereon. The substrate 26 is then removed from the oven 24 and transported to a coater station (not shown) in which a photoresist layer 30 is deposited on the substrate 26.

One of the drawbacks associated with the conventional primer application system 8 is that the nitrogen inlet pipe 16 directs the single stream of nitrogen gas 18 at a pressure of typically about 50 Kpa against a relatively small area of the liquid HMDS 12. This considerable impact energy between the gas 18 and the liquid HMDS 12 generates HMDS droplets 32 (FIG. 2) which are drawn with the HMDS vapor 22 into the oven 24, where the HMDS droplets 32 are deposited onto the surface of the substrate 26 with the HMDS primer layer 23. The presence of the HMDS droplets 32 on the substrate 26 causes uneven etching of the photoresist layer 30 during later processing, as shown in FIG. 2. Furthermore, such an event necessitates thorough flushing of the vapor outlet tube 20 to remove the HMDS droplets 32 therefrom, a procedure which requires about 2 hours of down-time for the primer application system 8. Accordingly, a novel mechanism is needed to provide a more even distribution of the nitrogen gas against the surface of HMDS liquid in a buffer tank to reduce the energy of impact between the gas and the primer liquid and eliminate or at least reduce the formation of HMDS droplets in the tank.

An object of the present invention is to provide an apparatus which is suitable for eliminating or reducing liquid contamination of a substrate during substrate priming.

Another object of the present invention is to provide an apparatus which is suitable for increasing the yield of devices on a substrate.

Still another object of the present invention is to provide an apparatus which is suitable for reducing the formation of droplets in a primer buffer tank as primer vapor is generated for the priming of substrates.

Yet another object of the present invention is to provide an apparatus which is suitable for primer buffer tanks that use liquid HMDS (hexamethyldisilazone) or other primer to prime substrates for photoresist deposition.

A still further object of the present invention is to provide a nozzle assembly which is suitable for a primer buffer tank used to generate a primer vapor for the priming of substrates.

Yet another object of the present invention is to provide a nozzle assembly which facilitates distribution of nitrogen or other gas against the surface of a liquid primer over a relatively large area to eliminate or substantially reduce the formation of primer droplets in the priming of substrates.

Another object of the present invention is to provide a primer tank having a nozzle assembly which distributes nitrogen or other gas against the surface of a liquid primer in such a manner as to prevent or at least minimize the production of potential substrate-contaminating primer droplets in the tank.

### SUMMARY OF THE INVENTION

In accordance with these and other objects and advantages, the present invention is generally directed to a primer tank having a nozzle assembly which uniformly distributes nitrogen or other vapor-generating gas against a primer liquid in the tank to generate a primer vapor for the priming of a semiconductor wafer substrate. The nozzle assembly may include a conduit to which is confluently attached a nozzle head having a nozzle plate. Multiple openings are provided in the nozzle plate to substantially uniformly distribute nitrogen or other inert gas against the surface of the primer liquid over a large area to generate a primer mist from the primer liquid and eliminate or at least substantially reduce the formation of primer droplets in the tank.

### BRIEF DESCRIPTION OF THE DRAWINGS

The invention will now be described, by way of example, with reference to the accompanying drawings, in which:

FIG. 1 is a schematic illustrating a typical conventional primer application system used to prime substrates;

FIG. 2 is a cross-sectional view of a substrate coated with primer using a conventional primer application system, with a primer layer and photoresist layer thereon and more particularly illustrating primer droplets embedded in the photoresist layer;

FIG. 3 is a schematic of a primer application system which utilizes a nozzle assembly according to the present invention;

FIG. 4 is a cross-sectional view, partially in section, of a nozzle assembly of the present invention; and

FIG. 5 is a bottom view of a nozzle plate element of the nozzle assembly.

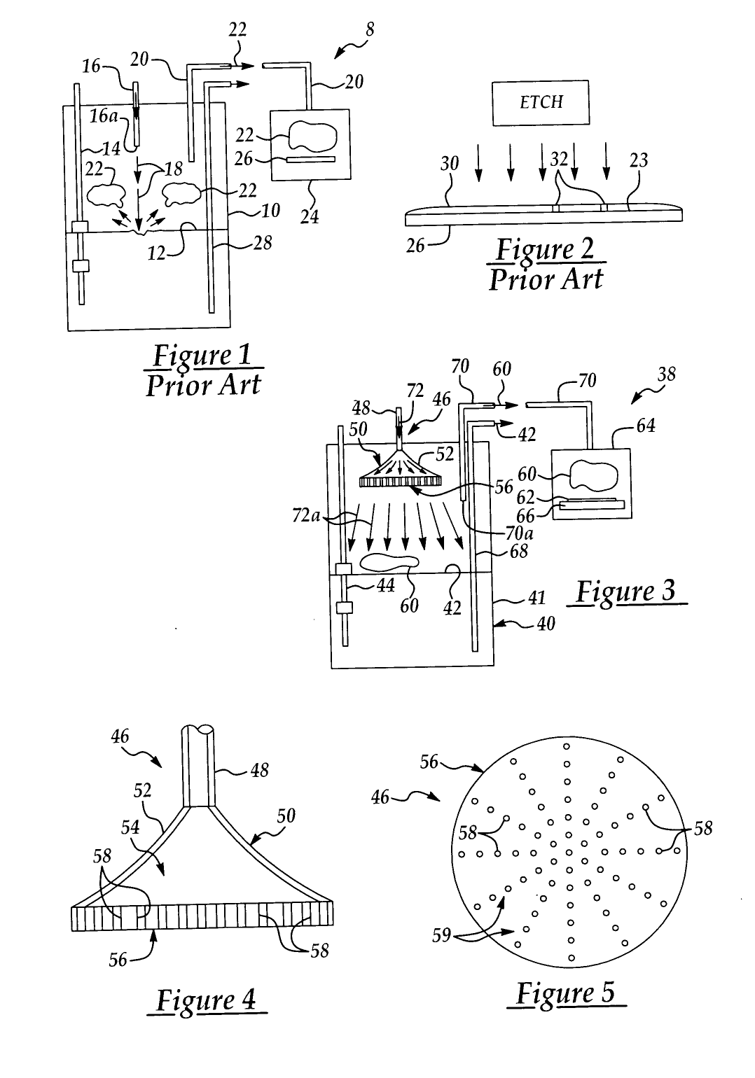

### DESCRIPTION OF THE PREFERRED EMBODIMENTS

The present invention has particularly beneficial utility in the generation of a primer vapor to prime semiconductor wafer substrates prior to deposition of a photoresist on the substrates in the fabrication of semiconductor integrated circuits. However, while references may be made to such semiconductor wafer substrates, the invention may be more broadly applicable to generating a vapor for priming substrates in a variety of industrial applications.

The present invention is generally directed to a primer tank having a nozzle assembly which uniformly disperses nitrogen or other vapor-generating gas in multiple gas streams of relatively low energy against a primer liquid in the tank to generate a primer vapor for the priming of a semiconductor wafer substrate. The nozzle assembly may include a conduit to which is confluently attached a nozzle head having a nozzle plate. Multiple nozzle openings are provided in the nozzle plate in a selected pattern to substantially uniformly distribute multiple streams of nitrogen or other inert gas against the surface of the primer liquid to generate a primer vapor from the primer liquid. The dispersed flow of the nitrogen or other gas reduces the energy of impact between each gas stream and the liquid primer, thereby eliminating or at least substantially reducing the formation of primer droplets which would otherwise be drawn from the tank into the oven or chamber in which the primer is applied to the substrate.

Referring to FIGS. 3-5, an illustrative embodiment of the primer application system of the present invention is generally indicated by reference numeral 38. The primer application system 38 includes a primer tank 40 having a tank body 41 which holds a supply of liquid primer 42 for the priming of a wafer substrate 66 in an oven or process chamber 64, as shown in FIG. 3 and hereinafter described. The tank body 41 may have a diameter of typically about 15 cm, although the diameter may be larger or smaller depending on the particular application of the primer application system 38. The liquid primer 42 may be liquid HMDS (hexamethyldisilazone), for example, or any other primer which is suitable for the priming of substrates. A level sensor 44 may be provided in the tank body 41 to sense the level of liquid primer 42 in the tank body 41. A vapor outlet tube 70 extends from the tank body 41 and is confluently connected to the oven or process chamber 64 in which the substrate 66 is placed, which process chamber 64 may be conventional. The vapor inlet end 70a of the vapor outlet tube 70 is disposed above the surface of the liquid primer 42. A drain pipe 68 may extend from the tank body 41 for the draining of residual or excess liquid primer 42 from the tank body 41, as needed.

A nozzle assembly 46 is provided in the tank body 41 and includes a gas inlet pipe 48 which is connected to a source (not shown) of nitrogen or other inert gas. A nozzle head 50 includes a housing 52 that is confluently connected to the inlet pipe 48 and defines a housing interior 54. A nozzle plate 56 having multiple nozzle openings 58 extending therethrough is provided on the housing 52 and closes the housing interior 54. The nozzle plate 56 may have a diameter of about 5 cm, and each of the nozzle openings 58 may have a diameter of typically about 1-3 mm. As shown in FIG. 5, the nozzle head 50 may include sixty-seven nozzle openings 58 which extend through the nozzle plate 56 in multiple, radially-extending rows 59. However, it is understood that a greater or lesser number of the nozzle openings 58 may extend through the nozzle plate 56 in any suitable alternative pattern or configuration.

Referring again to FIG. 3, in application of the primer application system 38, the substrate 66 is initially placed in the process chamber 64, the interior of which is adjusted to a reduced pressure and elevated temperature for priming of the substrate 66. Such reduced pressure and elevated temperature vary depending on the particular application and are known by those skilled in the art. An inert gas, such as nitrogen, is flown as a primary gas stream 72 through the inlet pipe 48 and into the housing interior 54 (FIG. 4) of the nozzle assembly 46, and then from the nozzle head 50 through the respective nozzle openings 58 of the nozzle plate 56 as multiple secondary gas streams 72a. The pressure of the gas in the primary gas stream 72 is typically about 50 Kpa. The secondary gas streams 72a strike the surface of the liquid primer 42 in a dispersed pattern. Accordingly, upon striking the liquid primer 42, the secondary gas streams 72a generate a substantially droplet-free primer vapor 60 in the tank body 41 of the primer tank 40. Because the interior of the process chamber 64 is maintained at a reduced pressure, the primer vapor 60 is drawn from the tank body 41 through the vapor outlet tube 70 and into the process chamber 64, where the primer vapor 60 forms a primer layer 62 on the substrate 66.

Throughout the substrate-priming operation, the level sensor 44 may be used to monitor the level of the liquid primer 42 in the tank body 41. Additional liquid primer 42 may be added to the tank body 41, as needed. After the priming operation is completed, further flow of the primary gas stream 72 through the nozzle assembly 46 is terminated, the vacuum seal on the process chamber 64 is broken, and the substrate 66 is removed from the process chamber 64 and transported to a photoresist-coating station for coating of photoresist (not shown) on the primer layer 62. The liquid primer 42 which remains in the tank body 41 may be removed therefrom through the drain pipe 68, as needed.

It will be appreciated by those skilled in the art that the nozzle head 50 separates the primary gas stream 72 into the multiple secondary gas streams 72a, which strike the surface of the liquid primer 42 in a dispersed pattern that generally matches the pattern of the nozzle openings 58 in the nozzle plate 56. Accordingly, each of the multiple secondary gas streams 72a strikes the liquid primer 42 at a substantially reduced gas pressure of typically about 0.75 Kpa. This optimizes generation of primer vapor 60 in the tank body 41 while preventing or substantially reducing the formation of liquid primer droplets which would otherwise be drawn with the primer vapor 60 into the process chamber 64 through the vapor outlet tube 70 and contaminate the wafer substrate 66 therein. Consequently, the primer layer 62 deposited on the substrate 66 is substantially uniform in thickness and lacks liquid primer droplets which would otherwise cause uneven etching of a photoresist layer (not shown) deposited on the primer layer 62 in subsequent processing steps.

While the preferred embodiments of the invention have been described above, it will be recognized and understood that various modifications can be made in the invention and the appended claims are intended to cover all such modifications which may fall within the spirit and scope of the invention.

1. A primer tank for generating a primer vapor, comprising:
a tank body for containing a liquid primer; and
a nozzle assembly having a plurality of nozzle openings provided in said tank body for ejecting a plurality of gas streams against the liquid primer.

2. The primer tank of claim 1 wherein said nozzle assembly comprises a gas inlet pipe for receiving a primary gas stream and a nozzle plate provided in fluid communication with said gas inlet pipe, and wherein said plurality of nozzle openings extends through said nozzle plate.

3. The primer tank of claim 1 further comprising a level sensor provided in said tank body for sensing a level of the liquid primer in said tank body.

4. The primer tank of claim 3 wherein said nozzle assembly comprises a gas inlet pipe for receiving a primary gas stream and a nozzle plate provided in fluid communication with said gas inlet pipe, and wherein said plurality of nozzle openings extends through said nozzle plate.

5. The primer tank of claim 1 further comprising a vapor outlet tube provided in fluid communication with said tank body for distributing the primer vapor from said tank body.

6. The primer tank of claim 5 wherein said nozzle assembly comprises a gas inlet pipe for receiving a primary gas stream and a nozzle plate provided in fluid communication with said gas inlet pipe, and wherein said plurality of nozzle openings extends through said nozzle plate.

7. The primer tank of claim 5 further comprising a level sensor provided in said tank body for sensing a level of the liquid primer in said tank body.

8. The primer tank of claim 7 wherein said nozzle assembly comprises a gas inlet pipe for receiving a primary gas stream and a nozzle plate provided in fluid communication with said gas inlet pipe, and wherein said plurality of nozzle openings extends through said nozzle plate.

9. A primer tank for generating a primer vapor, comprising:
a tank body for containing a liquid primer; and
a nozzle assembly provided in said tank body, said nozzle assembly having a gas inlet pipe for receiving a primary gas stream; a housing having a housing interior provided in fluid communication with said gas inlet pipe; and a nozzle plate having plurality of nozzle openings carried by said housing for receiving the primary gas stream and ejecting a plurality of secondary gas streams against the liquid primer.

10. The primer tank of claim 9 further comprising a level sensor provided in said tank body for sensing a level of the liquid primer in said tank body.

11. The primer tank of claim 9 further comprising a vapor outlet tube provided in fluid communication with said tank body for distributing the primer vapor from said tank body.

12. The primer tank of claim 11 further comprising a level sensor provided in said tank body for sensing a level of the liquid primer in said tank body.

13. The primer tank of claim 9 wherein said plurality of nozzle openings are arranged in a plurality of radially-extending rows in said nozzle plate.

14. The primer tank of claim 13 further comprising a level sensor provided in said tank body for sensing a level of the liquid primer in said tank body.

15. The primer tank of claim 13 further comprising a vapor outlet tube provided in fluid communication with said tank body for distributing the primer vapor from said tank body.

16. The primer tank of claim 15 further comprising a level sensor provided in said tank body for sensing a level of the liquid primer in said tank body.

17. A method of generating a primer vapor from a liquid primer, comprising the steps of:
providing a primer tank having a tank body;
providing the liquid primer in said tank body; and
directing an inert gas against the liquid primer in a plurality of gas streams.

18. The method of claim 17 wherein said liquid primer comprises hexamethyldisilazone.

19. The method of claim 17 wherein each of said plurality of gas streams has a pressure of about 0.75 Kpa.

20. The method of claim 17 wherein said directing an inert gas against the liquid primer in a plurality of gas streams comprises the steps of providing a primary gas stream, dividing said primary gas stream into said plurality of gas streams, and directing said plurality of gas streams against the liquid primer.
